(19) United States
(12) Patent Application Publication
(10) Pub. No.: US 2024/0006530 A1
(43) Pub. Date: Jan. 4, 2024

(54) HIGH VOLTAGE DEVICE HAVING MULTI-FIELD PLATES AND MANUFACTURING METHOD THEREOF

(71) Applicant: Richtek Technology Corporation, Hsinchu (TW)

(72) Inventor: Han-Chung TAI, Hsinchu (TW)

(21) Appl. No.: 18/299,074

(22) Filed: Apr. 12, 2023

(30) Foreign Application Priority Data
Jun. 30, 2022 (TW) 111124484

(51) Int. Cl. H01L 29/78; H01L 29/40; H01L 29/66

(52) U.S. Cl. CPC H01L 29/7816; H01L 29/404; H01L 29/66681

(57) ABSTRACT

A high voltage device having multi-field plates, includes: a semiconductor layer; a well; a body region; a source and a drain; a gate; a resist protection oxide region, formed on a top surface of the semiconductor layer, in connection with the top surface, and located above a drift region and in connection with the drift region; and plural field plates formed above the resist protection oxide region, wherein the plural field plates are arranged in parallel with the gate along a width direction and the plural field plates are not directly connected with one another and are arranged in parallel with one another, wherein the field plates are located above the resist protection oxide region in a vertical direction.

### CROSS REFERENCE

The present invention claims priority to TW 111124484 filed on Jun. 30, 2022.

### BACKGROUND OF THE INVENTION

### Field of Invention

The present invention relates to a high-voltage device and a manufacturing method thereof, in particular to a high-voltage device having multi-field plates and a manufacturing method thereof.

### Description of Related Art

FIG. 1 shows a schematic cross-sectional view of a conventional laterally diffused metal oxide semiconductor (LDMOS) device. The dielectric layer 22 of the gate of the conventional LDMOS device 10 has two different heights. Such structure has drawbacks that the operable voltage range of the device is limited and the device performance is affected by the oxide quality.

In view of the above, the present invention provides a high-voltage device having multi-field plates and a manufacturing method thereof to overcome the drawbacks of the prior art device.

### SUMMARY OF THE INVENTION

From one perspective, the present invention provides a high-voltage device having multi-field plates, comprising: a semiconductor layer formed on a substrate, the semiconductor layer comprising an upper surface and a lower surface opposite to each other in a vertical direction; a well region, having a first conductivity type, formed in the semiconductor layer, wherein the well region is located under the upper surface and connected to the upper surface in the vertical direction; a body region, having a second conductivity type, formed in the well region, wherein the body region is located under the upper surface and connected to the upper surface in the vertical direction; a gate, formed on the upper surface of the semiconductor layer, wherein a part of the body region is located directly below the gate and connected to the gate in the vertical direction, so as to provide an inversion current channel for the high-voltage device having multi-field plates in a conduction operation; a resist protection oxide (RPO) region, formed on the upper surface and connected to the upper surface, and located on a drift region and connected to the drift region; a plurality of field plates formed on the resist protection oxide region, wherein the plurality of field plates are arranged in parallel with the gate along a width direction, and the plurality of field plates are not directly connected to each other and are arranged in parallel to each other, and the field plates are located on the resist protection oxide region in the vertical direction; and a source and a drain, having the first conductivity type, the source and the drain being formed under the upper surface and connected to the upper surface in the vertical direction, wherein the source and the drain are respectively located below and outside two sides of the gate, one in the body region and the other in the well region, wherein in a channel direction, the drift region is located between the drain and the body region, in the well region and near the upper surface, whereby the drift region provides a drift current channel for the high-voltage device having multi-field plates during the conduction operation.

In one embodiment, the field plates are connected to the resist protection oxide region by one of following ways: connecting the field plates and the resist protection oxide region by a contact plug; or sequentially connecting the field plates, a contact plug, a metal region, an oxide region, and the resist protection oxide region.

From one perspective, the present invention provides a manufacturing method of a high-voltage device having multi-field plates, comprising: forming a semiconductor layer on a substrate, the semiconductor layer having an upper surface and a lower surface opposite to each other in a vertical direction; forming a well region having a first conductivity type in the semiconductor layer, wherein the well region is located under the upper surface and connected to the upper surface in the vertical direction; forming a body region having a second conductivity type in the well region, wherein the body region is located under the upper surface and connected to the upper surface in the vertical direction; forming a gate on the upper surface of the semiconductor layer, wherein a part of the body region is located directly below the gate and connected to the gate in the vertical direction, so as to provide an inversion current channel for the high-voltage device having multi-field plates in a conduction operation; forming a resist protection oxide (RPO) region on the upper surface and connecting to the upper surface, wherein the resist protection oxide region is located on a drift region and connected to the drift region; forming a plurality of field plates on the resist protection oxide region, wherein the plurality of field plates are arranged in parallel with the gate along a width direction, the plurality of field plates are not directly connected to each other and are arranged in parallel to each other, and the field plates are located on the resist protection oxide region in the vertical direction; and forming a source and a drain under the upper surface and connected to the upper surface in the vertical direction, wherein the source and the drain are respectively located below and outside two sides of the gate, one in the body region and the other in the well region, wherein in a channel direction, the drift region is located between the drain and the body region, in the well region and near the upper surface, whereby the drift region provides a drift current channel for the high-voltage device having multi-field plates during the conduction operation.

In one embodiment, the resist protection oxide region does not comprise a local oxidation of silicon (LOCOS) structure, a shallow trench isolation (STI) structure, nor a gate oxide layer.

In one embodiment, the field plate closest to the gate is connected to either the gate or the source by a conductive connection structure.

In one embodiment, the field plate closest to the drain is electrically floating or connected to the drain by a conductive connection structure.

In one embodiment, the resist protection oxide region is a continuous structure wherein all parts of the resist protection oxide region are connected together.

In one embodiment, except for the field plate closest to the gate, the other field plates are electrically floating, and by induced electric field, voltages of the other field plates are in a range between a voltage of the gate and a voltage of the drain, so as to reduce an electric field gradient of the drift region and reduce hot carrier injection (HCI) effect during operation of the high-voltage device having multi-field plates.

In one embodiment, the field plates are connected to the resist protection oxide region by one of following ways: connecting the field plates and the resist protection oxide region by a contact plug; or forming a contact plug, a metal region, and an oxide region, to connect the field plates to the resist protection oxide region.

In one embodiment, the field plates include a material of titanium nitride or tantalum nitride, and a thickness of the field plates is approximately 500 angstrom (Å).

In one embodiment, the oxide region is formed by a high aspect ratio process (HARP), or by a low temperature deposition process of plasma enhanced chemical vapor deposition (PECVD), or by a process using a material comprising tetraethoxysilane (TEOS), and a thickness of the oxide region is approximately 2000 Å.

In one embodiment, the resist protection oxide region is formed by a low pressure chemical vapor deposition (LPCVD) process, and a thickness of the resist protection oxide region is approximately 1000 Å.

Advantages of the present invention include: that the present invention has a low conduction resistance, a low figure of merit (FOM), and a high breakdown voltage (BV), by the multiple field plates.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic cross-sectional view of an LDMOS device of a conventional art.

FIG. 2A is a schematic cross-sectional view showing a high-voltage device having multi-field plates according to an embodiment of the present invention.

FIG. 2B is a schematic top view showing a high-voltage device having multi-field plates according to an embodiment of the present invention.

FIG. 3 is a schematic cross-sectional view showing a high-voltage device having multi-field plates according to another embodiment of the present invention.

FIG. 4 is a schematic cross-sectional view showing a high-voltage device having multi-field plates according to yet another embodiment of the present invention.

FIGS. 5A to 5O are schematic cross-sectional views illustrating a manufacturing method of a high-voltage device having multi-field plates according to an embodiment of the present invention.

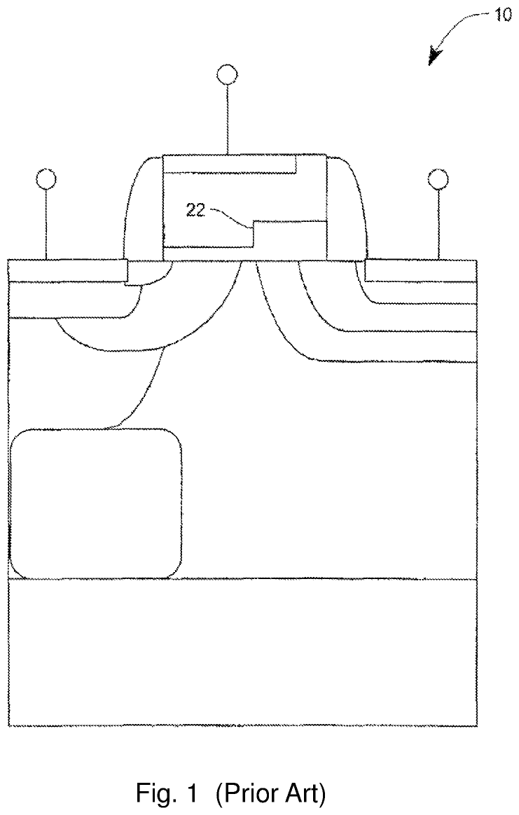

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

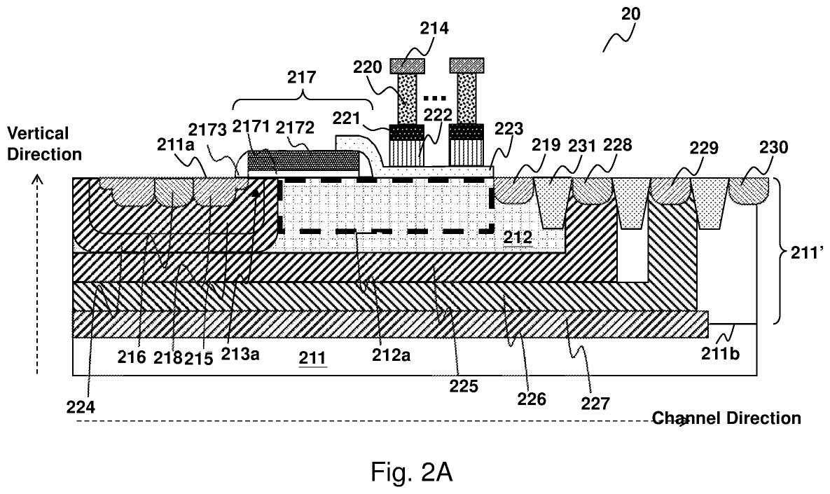

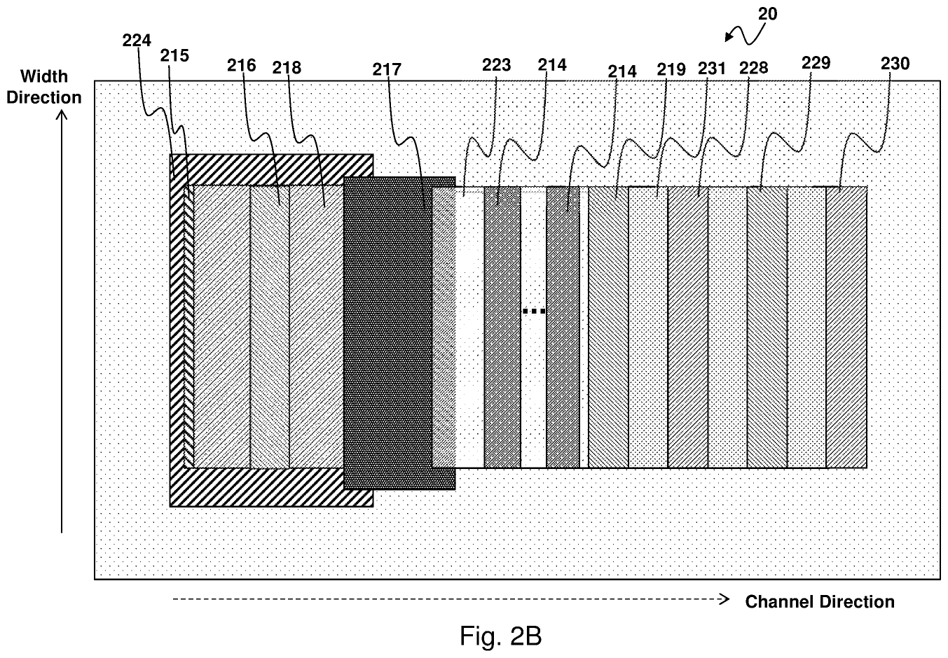

FIG. 2A is a schematic cross-sectional view showing a high-voltage device having multi-field plates according to an embodiment of the present invention. As shown in FIG. 2A, the high-voltage device having multi-field plates 20 of the present invention includes a semiconductor layer 211′, a first well region 212, a second well region 224, a body region 215, a gate 217, a resist protection oxide region 223, plural field plates 214, a body electrode 216, a source 218, a drain 219, a contact plug 220, a metal region 221, an oxide region 222, a second deep well region 225, a first deep well region 226, and a buried layer 227. The semiconductor layer 211′ is formed on the substrate 211, and the semiconductor layer 211′ has an upper surface 211a and a lower surface 211b opposite to each other in a vertical direction (as indicated by the dashed line arrow in FIG. 2A, same below). The substrate 211 is, for example, but not limited to, a P-type or N-type semiconductor silicon substrate. The semiconductor layer 211′ is formed on the substrate 211 by, for example, an epitaxial step, or a part of the substrate 211 is used as the semiconductor layer 211′. The method of forming the semiconductor layer 211′ is well known to those skilled in the art, so it is not redundantly explained here.

The first well region 212 which has a first conductivity type is formed in the semiconductor layer 211′, and in the vertical direction, the first well region 212 is located under the upper surface 211a and connected to the upper surface 211a. The second well region 224 which has the second conductivity type is formed in the semiconductor layer 211′, and in the vertical direction, the second well region 224 is located under the upper surface 211a and connected to the upper surface 211a. The body region 215 which has the second conductivity type is formed in the second well region 224, and in the vertical direction, the body region 215 is located under the upper surface 211a and connected to the upper surface 211a. The body electrode 216 has the second conductivity type and serves as an electrical contact of the body region 215. In the vertical direction, the body electrode 216 is formed under the upper surface 211a and connected to the body region 215.

The gate 217 is formed on the upper surface 211a of the semiconductor layer 211′. As seen from the top view of FIG. 2B, the gate 217 is substantially a rectangle extending in a width direction (as indicated by the solid line arrow in FIG. 2B), and in the vertical direction, a part of the body region 215 is located directly below the gate 217 and connected to the gate 217 to provide an inversion current channel 213a for the high-voltage device having multi-field plates 20 in a conduction operation. A resist protection oxide (RPO) region 223 is formed on the upper surface 211a and connected to the upper surface 211a, and is located on the drift region 212a (shown by thick dotted frame in FIG. 2A) and connected to the drift region 212a. Plural field plates 214 are formed on the resist protection oxide region 223, and the plural field plates 214 are arranged in parallel with the gate 217 along the width direction. The plural field plates 214 are not directly connected to each other and are arranged in parallel with each other, and in the vertical direction, the field plates 214 are located on the resist protection oxide region 223.

The source 218 and the drain 219 have the first conductivity type. In the vertical direction, the source 218 and the drain 219 are formed under the upper surface 211a and are connected to the upper surface 211a, and the source 218 and the drain 219 are located below and outside of the gate 217, respectively located in the body region 215 and in a part of the first well region 212 which is away from the body region 215. In a channel direction (as indicated by dashed line arrow in FIG. 2A), the drift region 212a is located between the drain 219 and the body region 215, and located in the first well region 212 near the upper surface 211a, to serve as a drift current channel for the high-voltage device having multi-field plates 20 during the conduction operation.

The second deep well region 225 which has a second conductivity type is formed below the first well region 212 and the second well region 224 in the vertical direction, and is connected to the first well region 212 and the second well region 224. The second deep well region 225 completely covers the underside of the first well region 212 and the second well region 224 and a side of the first well region 212. The first deep well region 226 which has the first conductivity type is formed below the second deep well region 225 and connected to the second deep well region 225 in the vertical direction. The first deep well region 226 completely covers the underside of the second deep well region 225. The buried layer 227 which has the first conductivity type is formed below the first deep well region 226 and connected to the first deep well region 226 in the vertical direction. The buried layer 227 completely covers the underside of the first deep well region 226. In the vertical direction, the buried layer 227 is formed at both sides of the interface between the substrate 211 and the semiconductor layer 211′, that is, a part of the buried layer 227 is located in the substrate 211, and a part of the buried layer 227 is located in the semiconductor layer 211′.

The electrical contact 228 is formed under the upper surface 211a and connected to the second deep well region 225. The electrical contact 229 is formed under the upper surface 211a and connected to the first deep well region 226. The electrical contact 230 is formed under the upper surface 211a and connected to the upper surface 211a. The insulating structures 231 are formed between the drain 219 and the electrical contact 228, between the electrical contact 228 and the electrical contact 229, and between the electrical contact 229 and the electrical contact 230, respectively, and located under the upper surface 211a and connected to the upper surface 211a.

The resist protection oxide region 223 does not include a local oxidation of silicon (LOCOS) structure, a shallow trench isolation (STI) structure, or a gate oxide layer. In one embodiment, the field plate 214 closest to the gate 217 is connected to the gate 217 or the source 218 by a conductive connection structure. In one embodiment, the field plate 214 closest to the drain 219 is electrically floating or connected to the drain 219 by a conductive connection structure. In one embodiment, the resist protection oxide region 223 is a continuous structure wherein all parts of the resist protection oxide region are connected together. In one embodiment, except for the field plate 214 closest to the gate 217, the other field plates 214 are electrically floating, and by induced electric field, the voltages of the other field plates 214 are in a range between the voltage of the gate 217 and the voltage of the drain 219, so as to reduce an electric field gradient of the drift region 212a and reduce hot carrier injection (HCI) effect when the high-voltage device having multi-field plates 20 operates.

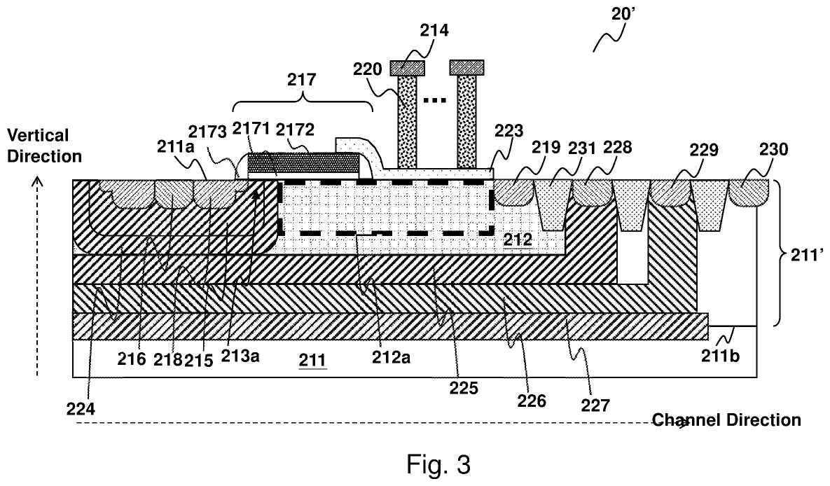

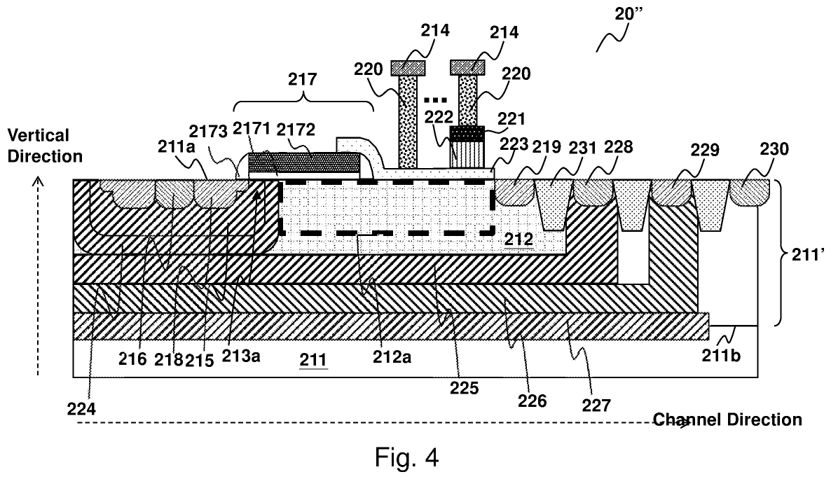

The field plate 214 is connected to the resist protection oxide region 223 by one of following ways: (1) connecting the field plate 214 and the resist protection oxide region 223 by a contact plug 220; or (2) sequentially connecting the field plate 214, the contact plug 220, the metal region 221, the oxide region 222, and the resist protection oxide region 223. The embodiment shown in FIG. 2A adopts the way of connecting the field plate 214, the contact plug 220, the metal region 221, the oxide region 222, and the resist protection oxide region 223 sequentially. The embodiments shown in FIG. 3 adopts the way of connecting the field plate 214 and the resist protection oxide region 223 by the contact plug 220. The embodiment shown in FIG. 4 is a hybrid type, that is, a part of the field plates 214 is connected to the field plate 214 and the resist protection oxide region 223 by way of the contact plug 220, and the other part of the field plate 214 adopts the way of sequentially connecting the field plate 214, the contact plug 220, the metal region 221, the oxide region 222, and the resist protection oxide region 223.

In one embodiment, the material of the field plate 214 is, for example, but not limited to, titanium nitride or tantalum nitride. In one embodiment, the thickness of the field plate 214 is approximately 500 angstrom (Å). In one embodiment, the oxide region 222 is formed by a high aspect ratio process (HARP), by a low temperature deposition process of plasma enhanced chemical vapor deposition (PECVD), or by a process using a material including tetraethoxysilane (TEOS). In one embodiment, the thickness of the oxide region 222 is approximately 2000 Å.

In one embodiment, the resist protection oxide region 223 is formed by a low pressure chemical vapor deposition (LPCVD) process. In one embodiment, the thickness of the resist protection oxide region 223 is approximately 1000 Å.

It should be noted that the term “inversion current channel” means thus. Taking this embodiment as an example, when the high voltage device 20 operates in conduction operation due to the voltage applied to the gate 217, an inverse layer is formed below the gate 217, to provide a channel for the conduction current to flow through, which is the inverse current channel known to a person having ordinary skill in the art, so the details thereof are not redundantly explained here.

It should be noted that the term “drift current channel” means thus. Taking this embodiment as an example, the drift current channel refers to a region where the conduction current passes through in a drifting manner when the high-voltage device operates in conduction operation, which is known to a person having ordinary skill in the art, so the details thereof are not redundantly explained here.

It should be noted that the upper surface 211a as referred to does not mean a completely flat plane, but refers to a surface of the semiconductor layer 211′.

It should be noted that the gate 217 includes a conductive layer 2172, a dielectric layer 2171 connected to the upper surface 211a, and a spacer layer 2173 having electrical insulating properties, which are well known to those with ordinary knowledge in the art, and will not be repeated here.

It should be noted that the aforementioned “first conductivity type” and “second conductivity type” mean that impurities of corresponding conductivity types are doped in regions of the high voltage MOS device (for example but not limited to the aforementioned first well region, second well region, first deep well region, second deep well region, buried layer, body region, body electrode, source, and drain, etc.), so that the regions have the corresponding conductivity type, wherein the first conductivity type for example is N-type and the second conductivity type is P-type, or the opposite).

In addition, the term “high voltage device” refers to a transistor device wherein a voltage applied to the drain thereof in normal operation is higher than a specific voltage, such as 5V. A lateral distance (i.e., a length of the drift region) between the body region 215 and the drain 219 of the high voltage device is determined according to the required operation voltage during normal operation, so that the device can operate at or higher than the aforementioned specific voltage, which is known to a person having ordinary skill in the art, so the details thereof are not redundantly explained here.

The present invention is superior to the conventional art in that: according to the present invention, taking the embodiment shown in FIGS. 2A and 2B as an example, the plural field plates 214 are formed in the resist protection oxide region 223, and are arranged in parallel with the gate 217, wherein the field plate 214 closest to the gate 217 is connected to the gate 217 or the source 218 by a conductive connection structure, and the field plate 214 closest to the drain 219 is electrically floating connected or connected to the drain 219 by a conductive connection structure, and the other field plates 214 are electrically floating, whereby the voltages of the other field plates 214 are in a range between the voltage of the gate 217 and the voltage of the drain 219 by induced electric field; hence, the electric field gradient of the drift region 212a and hot carrier injection (HCI) effect can be reduced when the high-voltage device having multi-field plates 20 operates.

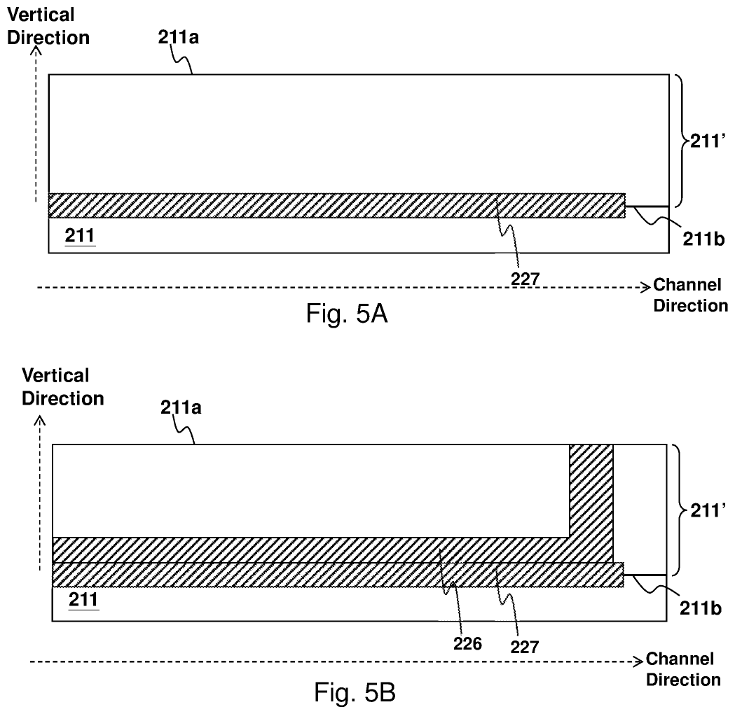

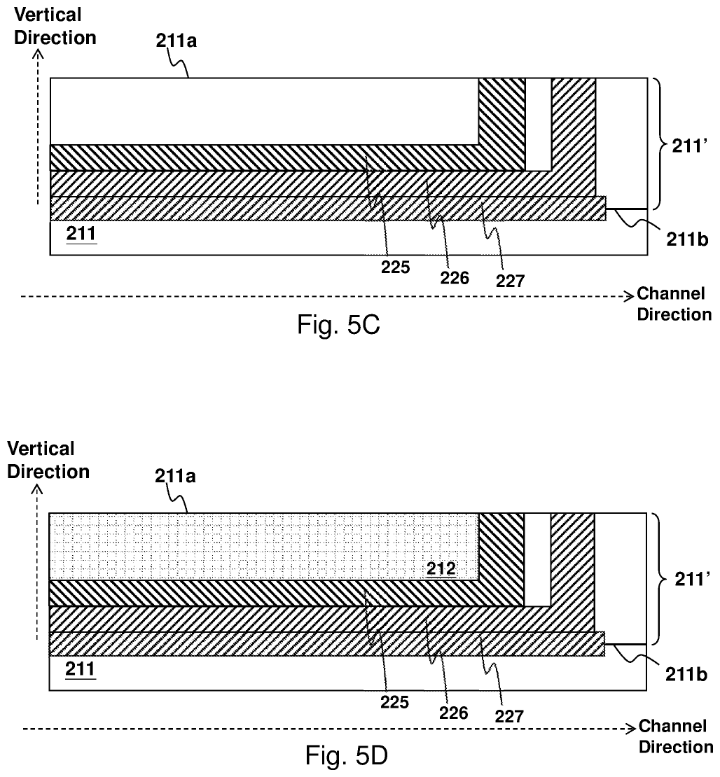

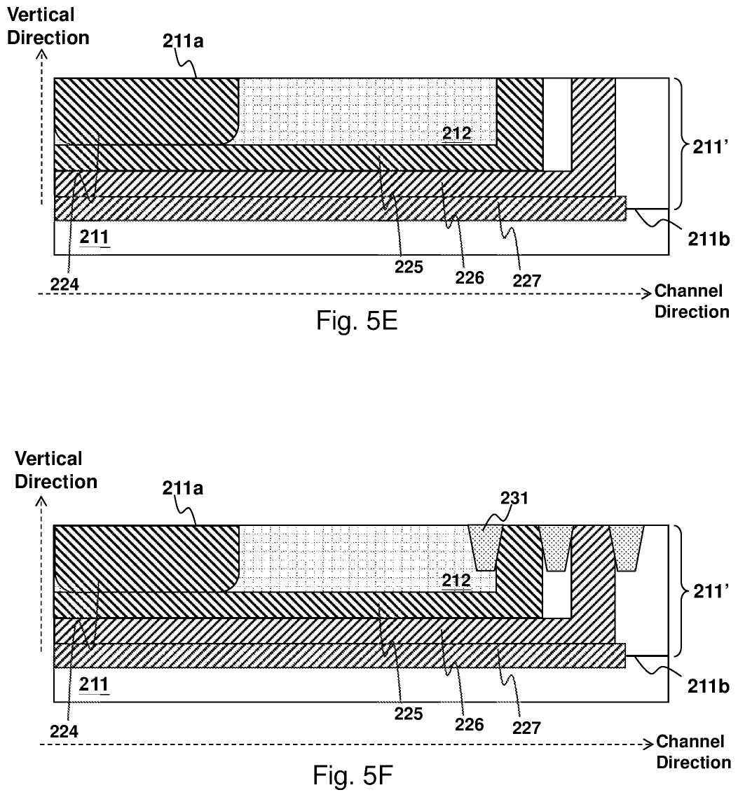

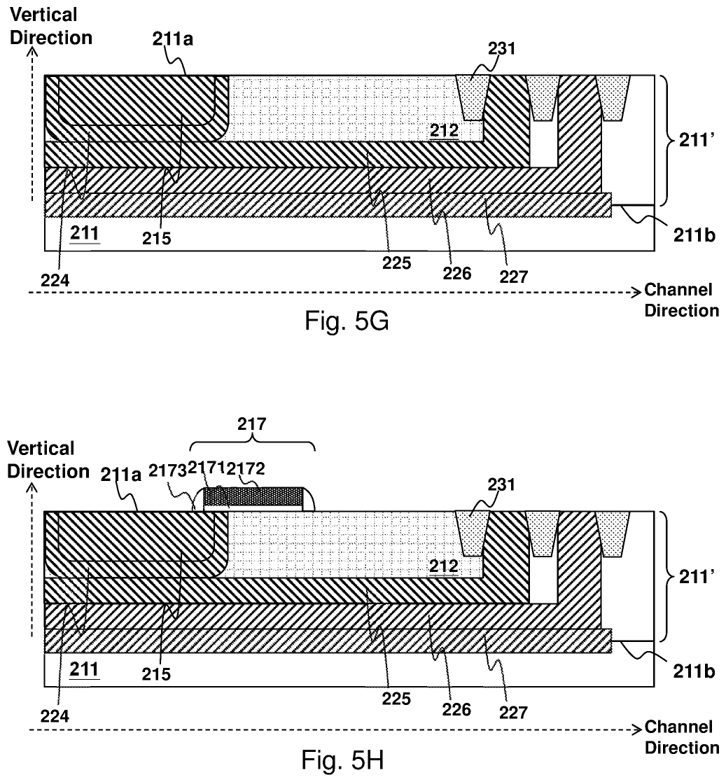

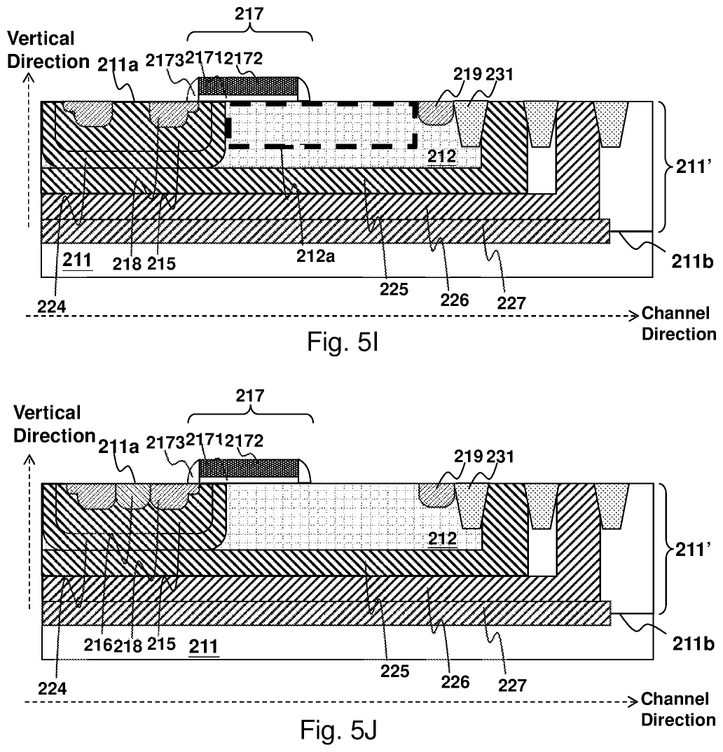

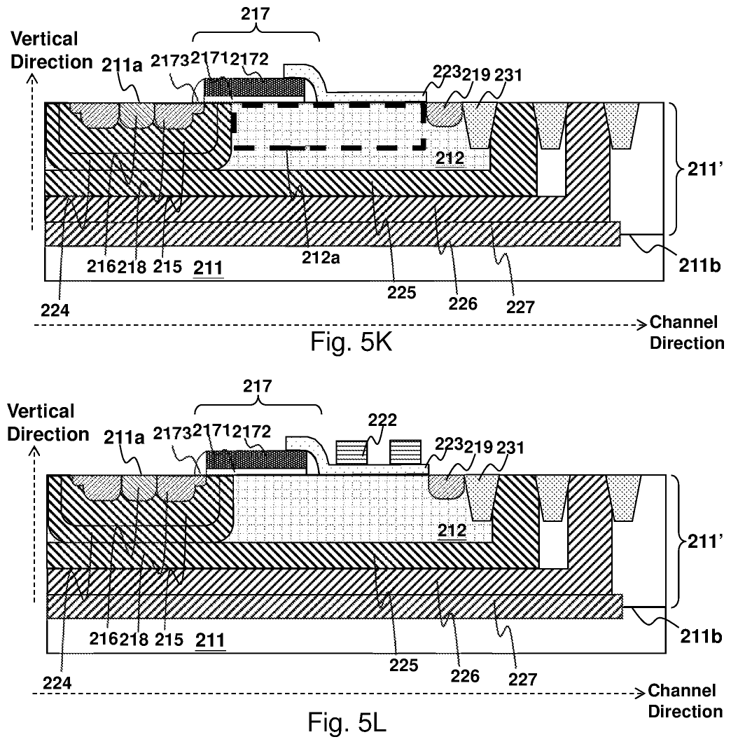

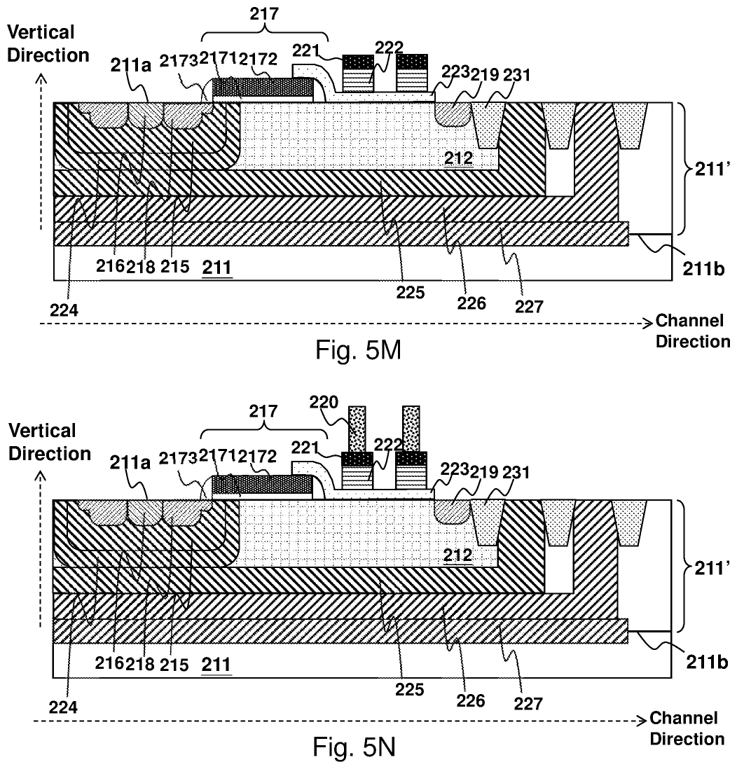

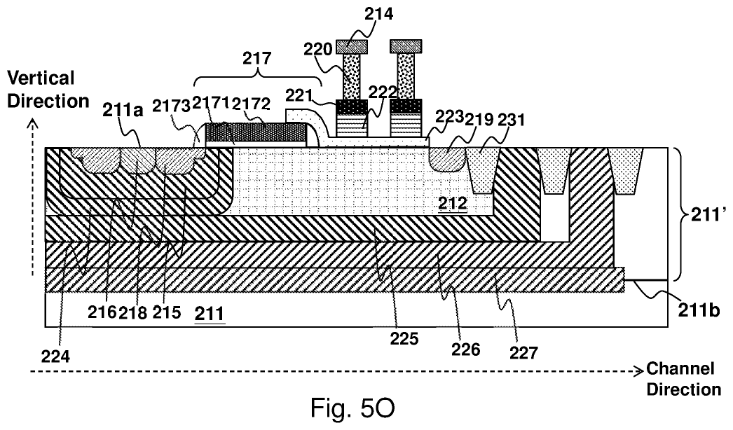

Please refer to FIG. 5A to FIG. 5O, which are schematic cross-sectional views illustrating a manufacturing method of a high-voltage device having multi-field plates according to an embodiment of the present invention. As shown in FIG. 5A, a semiconductor layer 211′ is first formed on the substrate 211, wherein the semiconductor layer 211′ has an upper surface 211a and a lower surface 211b opposite to each other in the vertical direction. The substrate 211 is, for example, but not limited to, a P-type or N-type semiconductor silicon substrate. The semiconductor layer 211′ is formed on the substrate 211 by, for example, an epitaxial step, or a part of the substrate 211 used as the semiconductor layer 211′. The way of forming the semiconductor layer 211′ is well known to those skilled in the art, so the details thereof are not redundantly explained here. Subsequently, a buried layer 227 is formed on the substrate 211, for example, formed on both sides of the interface between the substrate 211 and the semiconductor layer 211′, that is, a part of the buried layer 227 is located in the substrate 211, and a part of the buried layer 227 is located in the semiconductor layer 211′. The buried layer 227 has a first conductivity type, which can be formed by, for example, an ion implantation process which implants impurities of the first conductivity type into the substrate 211 in a form of accelerated ions to form the buried layer 227.

Next, as shown in FIG. 5B, a first deep well region 226 is formed above the buried layer 227, so that the buried layer 227 completely covers the underside of the first deep well region 226. The first deep well region 226 has the first conductivity type, which can be formed by, for example but not limited to, using a photoresist layer formed by a lithography process as a mask, and doping the first conductivity type impurities into the semiconductor layer 211′ to form the first deep well region 226. In the present embodiment, an ion implantation process is taken to implant impurities of the first conductivity type in the semiconductor layer 211′ in the form of accelerated ions to form the first deep well region 226.

Next, as shown in FIG. 5C, a second deep well region 225 is formed above the first deep well region 226, so that the first deep well region 226 completely covers the underside of the second deep well region 225. The second deep well region 225 has the second conductivity type, which can be formed by, for example but not limited to, forming a photoresist layer as a mask by a lithography process, and doping impurities of the second conductivity type into the semiconductor layer 211′ to form the second deep well region 225. In the present embodiment, an ion implantation process is taken to implant impurities of impurities of the second conductivity type in the semiconductor layer 211′ in the form of accelerated ions, to form the second deep well region 225.

Subsequently, as shown in FIG. 5D, a first well region 212 is formed in the semiconductor layer 211′ and above the second deep well region 225, so that the second deep well region 225 completely covers the underside of the first well region 212, and in the vertical direction, the first well region 212 is located below the upper surface 211a and connected to the upper surface 211a, wherein the first well region 212 has the first conductivity type. Next, as shown in FIG. 5E, a second well region 224 is formed in the semiconductor layer 211′ and above the second deep well region 225, so that the second deep well region 225 completely covers the underside of the second well region 224, and in the vertical direction, the second well region 224 is located below the upper surface 211a and connected to the upper surface 211a, wherein the second well region 224 has the second conductivity type.

Subsequently, as shown in FIG. 5F, an insulating structure 231 is formed under the upper surface 211a and connected to the upper surface 211a. Next, as shown in FIG. 5G, a body region 215 is formed in the second well region 224, so that in the vertical direction, the body region 215 is located below the upper surface 211a and connected to the upper surface 211a, wherein the body region 215 has the second conductivity type. Subsequently, as shown in FIG. 5H, a gate 217 is formed on the upper surface 211a of the semiconductor layer 211′, so that in the vertical direction, a part of the body region 215 is located directly under the gate 217 and connected to the gate 217, thereby providing an inversion current channel for the high-voltage device having multi-field plates during conduction operation.

Subsequently, as shown in FIG. 5I, in the vertical direction, the source 218 and the drain 219 are formed under the upper surface 211a and connected to the upper surface 211a, so that the source 218 and the drain 219 are located below and outside the gate 217, respectively located in the body region 215 and in a part of the first well region 212 which is away from the body region 215. The source 218 and the drain 219 have the first conductivity type, and in the channel direction, the drift region 212a is located between the drain 219 and the body region 215, and located in the first well region 212 closing to the upper surface 211a, to serve as a drift current channel for the high-voltage device having multi-field plates in conduction operation. The source 218 and the drain 219 can be formed by, for example but not limited to, forming a photoresist layer as a mask by a lithography process, and doping the first conductivity type impurities into the body region 215 and the first well region 212, respectively, to form the source 218 and the drain 219. In the present embodiment, an ion implantation process is taken to implant impurities of the first conductivity type in the form of accelerated ions into the body region 215 and the first well region 212 to form the source 218 and the drain 219.

Next, as shown in FIG. 5J, in the vertical direction, a body electrode 216 is formed under the upper surface 211a and connected to the body region 215 of the upper surface 211a. The body electrode 216 has the second conductivity type, which can be formed by, for example but not limited to, forming a photoresist layer as a mask by a lithography process step, and doping impurities of the second conductivity type into the body region 215 to form the body electrode 216. In the present embodiment, an ion implantation process is taken to implant impurities of the second conductivity type in the form of accelerated ions into the body region 215 to form the body electrode 216. Subsequently, as shown in FIG. 5K, a resist protection oxide (RPO) region 223 is formed on the upper surface 211a and connected to the upper surface 211a, so that the resist protection oxide region 223 is located on the drift region 212a and connected to the drift region 212a. Subsequently, as shown in FIG. 5L, plural oxide regions 222 are formed on the resist protection oxide region 223. After that, as shown in FIG. 5M, plural metal regions 221 are formed on the oxide regions 222. Subsequently, as shown in FIG. 5N, plural contact plugs 220 are formed on the metal regions 221. Next, as shown in FIG. 5O, plural field plates 214 are formed on the metal regions 221 and the plural field plates 214 are arranged in parallel with the gate 217 along the width direction, wherein the plural field plates 214 are not directly connected to each other and are arranged in parallel to each other, and in the vertical direction, the field plate 214 is located above the resist protection oxide region 223.

In an alternative embodiment, the steps of forming the metal region 221 and the oxide region 222 can be omitted. In this case the contact plug 220 is first directly formed on the resist protection oxide region 223, and then the field plate 214 is formed on the contact plug 220, so as to connect the field plate 214 with the resist protection oxide region 223. In yet another alternative embodiment, the above two methods of forming the field plates 214 can be combined; more specifically, for a part of the field plates 214, the contact plug 220 is formed to connect the field plate 214 and the resist protection oxide region 223, and for another part of the field plates 214, the oxide region 222, the metal region 221, the contact plug 220, and the field plates 214 are sequentially formed, so that this part of the field plates 214 is connected to the resist protection oxide region 223 through the oxide region 222, the metal region 221, and the contact plug 220.

The resist protection oxide region 223 does not include a local oxidation of silicon (LOCOS) structure, a shallow trench isolation (STI) structure or a gate oxide layer. In one embodiment, the field plate 214 closest to the gate 217 is connected to either the gate 217 or the source 218 by a conductive connection structure. In one embodiment, the field plate 214 closest to the drain 219 is electrically floating or connected to the drain 219 by a conductive connection structure. In one embodiment, the resist protection oxide region 223 is a a continuous structure wherein all parts of the resist protection oxide region 223 are connected together. In one embodiment, except for the field plate 214 closest to the gate 217, the other field plates 214 are electrically floating, and the voltages of the other field plates 214 are in a range between the voltage of the gate 217 and the voltage of the drain 219 by inducing an electric field, so as to reduce the electric field gradient of the drift region 212a and hot carrier injection (HCI) effect when the high-voltage device having multi-field plates 20 operates.

In one embodiment, the step of forming the plurality of field plates 214 on the resist protection oxide regions 223 includes one of the following steps: (1) forming contact plugs 220 to connect the field plates 214 and the resist protection oxide regions 223; or (2) sequentially forming the contact plugs 220, the metal regions 221, and the oxide regions 222 to connect the field plates 214 and the resist protection oxide regions 223. In one embodiment, the field plate 214 includes a material of, for example, but not limited to, titanium nitride or tantalum nitride. In one embodiment, the thickness of the field plate 214 is approximately 500 Å.

In one embodiment, the oxide region 222 is formed by a high aspect ratio (HARP) process or by a low temperature deposition process of plasma enhanced chemical vapor deposition (PECVD), or by a process using materials including tetraethoxysilane (TEOS). In one embodiment, a thickness of the oxide region 222 is approximately 2000 Å. In one embodiment, the resist protection oxide region 223 is formed by a low pressure chemical vapor deposition (LPCVD) process. In one embodiment, the thickness of the resist protection oxide region 223 is approximately 1000 Å.

As described above, the present invention can achieve low on-resistance, low figure of merit (FOM), and good breakdown voltage (BV) by providing multi-field plates.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography process step is not limited to the mask technology but it can also include electron beam lithography, immersion lithography, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A high-voltage device having multi-field plates, comprising:
a semiconductor layer formed on a substrate, the semiconductor layer comprising an upper surface and a lower surface opposite to each other in a vertical direction;
a well region, having a first conductivity type, formed in the semiconductor layer, wherein the well region is located under the upper surface and connected to the upper surface in the vertical direction;
a body region, having a second conductivity type, formed in the well region, wherein the body region is located under the upper surface and connected to the upper surface in the vertical direction;
a gate, formed on the upper surface of the semiconductor layer, wherein a part of the body region is located directly below the gate and connected to the gate in the vertical direction, so as to provide an inversion current channel for the high-voltage device having multi-field plates in a conduction operation;
a resist protection oxide (RPO) region, formed on the upper surface and connected to the upper surface, and located on a drift region and connected to the drift region;
a plurality of field plates formed on the resist protection oxide region, wherein the plurality of field plates are arranged in parallel with the gate along a width direction, and the plurality of field plates are not directly connected to each other and are arranged in parallel to each other, and the field plates are located on the resist protection oxide region in the vertical direction; and
a source and a drain, having the first conductivity type, the source and the drain being formed under the upper surface and connected to the upper surface in the vertical direction, wherein the source and the drain are respectively located below and outside two sides of the gate, one in the body region and the other in the well region,
wherein in a channel direction, the drift region is located between the drain and the body region, in the well region and near the upper surface, whereby the drift region provides a drift current channel for the high-voltage device having multi-field plates during the conduction operation.

2. The high-voltage device having multi-field plates of claim 1, wherein the resist protection oxide region does not comprise a local oxidation of silicon (LOCOS) structure, a shallow trench isolation (STI) structure, nor a gate oxide layer.

3. The high-voltage device having multi-field plates of claim 1, wherein the field plate closest to the gate is connected to either the gate or the source by a conductive connection structure.

4. The high-voltage device having multi-field plates of claim 1, wherein the field plate closest to the drain is electrically floating or connected to the drain by a conductive connection structure.

5. The high-voltage device having multi-field plates of claim 1, wherein the resist protection oxide region is a continuous structure wherein all parts of the resist protection oxide region are connected together.

6. The high-voltage device having multi-field plates of claim 3, wherein except for the field plate closest to the gate, the other field plates are electrically floating, and by induced electric field, voltages of the other field plates are in a range between a voltage of the gate and a voltage of the drain, so as to reduce an electric field gradient of the drift region and reduce hot carrier injection (HCI) effect during operation of the high-voltage device having multi-field plates.

7. The high-voltage device having multi-field plates of claim 1, wherein the field plates are connected to the resist protection oxide region by one of following ways:
connecting the field plates and the resist protection oxide region by a contact plug; or
sequentially connecting the field plates, a contact plug, a metal region, an oxide region, and the resist protection oxide region.

8. The high-voltage device having multi-field plates of claim 1, wherein the field plates include a material of titanium nitride or tantalum nitride, and a thickness of the field plates is approximately 500 angstrom (Å).

9. The high-voltage device having multi-field plates of claim 7, wherein the oxide region is formed by a high aspect ratio process (HARP), or by a low temperature deposition process of plasma enhanced chemical vapor deposition (PECVD), or by a process using a material comprising tetraethoxysilane (TEOS), and a thickness of the oxide region is approximately 2000 Å.

10. The high-voltage device having multi-field plates of claim 1, wherein the resist protection oxide region is formed by a low pressure chemical vapor deposition (LPCVD) process, and a thickness of the resist protection oxide region is approximately 1000 Å.

11. A manufacturing method of a high-voltage device having multi-field plates, comprising:
forming a semiconductor layer on a substrate, the semiconductor layer having an upper surface and a lower surface opposite to each other in a vertical direction;
forming a well region having a first conductivity type in the semiconductor layer, wherein the well region is located under the upper surface and connected to the upper surface in the vertical direction;
forming a body region having a second conductivity type in the well region, wherein the body region is located under the upper surface and connected to the upper surface in the vertical direction;
forming a gate on the upper surface of the semiconductor layer, wherein a part of the body region is located directly below the gate and connected to the gate in the vertical direction, so as to provide an inversion current channel for the high-voltage device having multi-field plates in a conduction operation;
forming a resist protection oxide (RPO) region on the upper surface and connecting to the upper surface, wherein the resist protection oxide region is located on a drift region and connected to the drift region;
forming a plurality of field plates on the resist protection oxide region, wherein the plurality of field plates are arranged in parallel with the gate along a width direction, the plurality of field plates are not directly connected to each other and are arranged in parallel to each other, and the field plates are located on the resist protection oxide region in the vertical direction; and
forming a source and a drain under the upper surface and connected to the upper surface in the vertical direction, wherein the source and the drain are respectively located below and outside two sides of the gate, one in the body region and the other in the well region,
wherein in a channel direction, the drift region is located between the drain and the body region, in the well region and near the upper surface, whereby the drift region provides a drift current channel for the high-voltage device having multi-field plates during the conduction operation.

12. The manufacturing method of the high-voltage device having multi-field plates of claim 11, wherein the resist protection oxide region does not comprise a local oxidation of silicon (LOCOS) structure, a shallow trench isolation (STI) structure, nor a gate oxide layer.

13. The manufacturing method of the high-voltage device having multi-field plates of claim 11, wherein the field plate closest to the gate is connected to either the gate or the source by a conductive connection structure.

14. The manufacturing method of the high-voltage device having multi-field plates of claim 11, wherein the field plate closest to the drain is electrically floating or connected to the drain by a conductive connection structure.

15. The manufacturing method of the high-voltage device having multi-field plates of claim 11, wherein the resist protection oxide region is a continuous structure wherein all parts of the resist protection oxide region are connected together.

16. The manufacturing method of the high-voltage device having multi-field plates of claim 13, wherein except for the field plate closest to the gate, the other field plates are electrically floating, and by induced electric field, voltages of the other field plates are in a range between a voltage of the gate and a voltage of the drain, so as to reduce an electric field gradient of the drift region and reduce hot carrier injection (HCI) effect during operation of the high-voltage device having multi-field plates.

17. The manufacturing method of the high-voltage device having multi-field plates of claim 11, wherein the step of forming the plurality of field plates on the resist protection oxide region comprises one of following steps:
forming a contact plug to connect the field plates and the resist protection oxide region; or
sequentially forming the contact plug, a metal region, and an oxide region to connect the field plates and the resist protection oxide region.

18. The manufacturing method of the high-voltage device having multi-field plates of claim 11, the field plates include a material of titanium nitride or tantalum nitride, and a thickness of the field plates is approximately 500 angstrom (Å).

19. The manufacturing method of the high-voltage device having multi-field plates of claim 17, wherein the oxide region is formed by a high aspect ratio process (HARP), or by a low temperature deposition process of plasma enhanced chemical vapor deposition (PECVD), or by a process using materials comprising tetraethoxysilane (TEOS), and a thickness of the oxide region is approximately 2000 Å.

20. The manufacturing method of the high-voltage device having multi-field plates of claim 11, wherein the resist protection oxide region is formed by a low pressure chemical vapor deposition (LPCVD) process, and a thickness of the resist protection oxide region is approximately 1000 Å.
